(19) United States
(12) Patent Application Publication
(10) Pub. No.: US 2012/0048607 A1
(43) Pub. Date: Mar. 1, 2012

(54) ELECTRONIC DEVICE

(75) Inventors: Tetsuya TAKAHASHI, Kawasaki (JP); Kenji KOBAE, Kawasaki (JP); Naoki ISHIKAWA, Kawasaki (JP); Takeshi MIYAKOSHI, Kawasaki (JP)

(73) Assignee: FUJITSU LIMITED, Kawasaki-shi (JP)

(21) Appl. No.: 13/198,749

(22) Filed: Aug. 5, 2011

(30) Foreign Application Priority Data
Aug. 25, 2010 (JP) 2010-188036

(51) Int. Cl. H05K 1/16

(52) U.S. Cl. 174/260

(57) ABSTRACT

An electronic device includes an electronic component having a mounting surface with a contour including a plurality of sides and a plurality of corners, a circuit board including a mounted surface that faces the mounting surface of the electronic component and having a recess formed at a position facing the corner of the electronic component, a connection portion provided between the electronic component and the circuit board and electrically connecting the circuit board to the electronic component, a first member embedded in the recess and having a rigidity lower than those of the electronic component and the circuit board, and a second member provided between the electronic component and the circuit board and having a rigidity lower than those of the electronic component and the circuit board.

### CROSS-REFERENCE TO RELATED APPLICATION

This application is based upon and claims the benefit of priority of the prior Japanese Patent Application No. 2010-188036, filed on Aug. 25, 2010, the entire contents of which are incorporated herein by reference.

### FIELD

The embodiment discussed herein is related to an electronic device in which an underfill material is filled between an electronic component and a circuit board.

### BACKGROUND

Owing to a demand for size reduction, thickness reduction, and density increase of electronic devices, so-called flip-chip mounting may be used in which a projecting electrode (bump) is formed on either an electronic component (e.g., a semiconductor chip) or a circuit board, thereby electrically connecting the electronic component to the circuit board.

In flip-chip mounting, an electronic component and a circuit board are connected to each other directly by a bump. Thus, when an electronic device is heated, a great load may occur in the bump connection portion owing to the difference in coefficient of thermal expansion between the electronic component and the circuit board. Therefore, a gap between the electronic component and the circuit board may be filled with an underfill material to reduce the load occurring in the bump connection portion.

As a flip-chip mounting method, for example, a technology is known in which a recess is formed in an IC or a board of a flip-chip package and filled with an underfill resin, thereby improving the bonding strength between the IC and the board (for example, Japanese Laid-open Patent Publication No. 2000-36517).

Meanwhile, the gap between the electronic component and the circuit board is reduced owing to size reduction, thickness reduction, and density increase of the electronic device. Accordingly, the thickness of the underfill material filled in the gap between the electronic component and the circuit board is also reduced. Thus, when the electronic device is heated, great stress occurs in the underfill material, and a crack may occur in the underfill material or the underfill material may separate from the electronic component or the circuit board. In particular, at a corner of the electronic component, great stress occurs in the underfill material. Thus, the underfill material is likely to separate from the electronic component or the circuit board. Therefore, it is necessary to consider a countermeasure against the separation of the underfill material at the corner of the electronic component.

### SUMMARY

According to an aspect of the invention, an electronic device includes an electronic component having a mounting surface with a contour including a plurality of sides and a plurality of corners, a circuit board including a mounted surface that faces the mounting surface of the electronic component and having a recess formed at a position facing the corner of the electronic component, a connection portion provided between the electronic component and the circuit board and electrically connecting the circuit board to the electronic component, a first member embedded in the recess and having a rigidity lower than those of the electronic component and the circuit board, and a second member provided between the electronic component and the circuit board and having a rigidity lower than those of the electronic component and the circuit board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a semiconductor device according to a first embodiment.

FIG. 2 is a cross-sectional view of the semiconductor device according to the first embodiment.

FIG. 3 is a side view of a semiconductor chip according to the first embodiment.

FIG. 4 is a bottom view of the semiconductor chip according to the first embodiment.

FIG. 5 is a plan view of a circuit board according to the first embodiment.

FIG. 6 is a partial cross-sectional view of the circuit board according to the first embodiment.

FIG. 7A to FIG. 7C are distribution diagrams of thermal stress occurring in an underfill resin of a semiconductor device according to Comparative Example 1 that does not have any recess.

FIG. 8A to FIG. 8C are distribution diagrams of thermal stress occurring in an underfill resin of a semiconductor device according to Comparative Example 2 in which recesses are provided at positions shifted by 0.25 mm outward from corners of a semiconductor chip.

FIG. 9A to FIG. 9C are distribution diagrams of thermal stress occurring in an underfill resin of a semiconductor device according to Comparative Example 3 in which recesses are provided at positions shifted by 1.05 mm inward from corners of a semiconductor chip.

FIG. 10A to FIG. 10C are distribution diagrams of thermal stress occurring in an underfill resin of a semiconductor device according to Example in which recesses are provided directly below corners of a semiconductor chip.

FIG. 11A to FIG. 11D are diagrams illustrating a method of manufacturing the semiconductor device according to the first embodiment.

FIG. 12A and FIG. 12B are diagrams illustrating a method of mounting the semiconductor device according to the first embodiment to another mounting board.

FIG. 13 is a partial cross-sectional view of a circuit board according to a modified example of the first embodiment.

FIG. 14 is a plan view of a circuit board according to a modified example of the first embodiment.

FIG. 15 is a plan view of a circuit board according to a modified example of the first embodiment.

FIG. 16 is a plan view of a circuit board according to a modified example of the first embodiment.

FIG. 17 is a plan view of a circuit board according to a modified example of the first embodiment.

FIG. 18 is a plan view of a circuit board according to a modified example of the first embodiment.

FIG. 19 is a perspective view of a semiconductor device according to a modified example of the first embodiment.

FIG. 20 is a cross-sectional view of the semiconductor device according to the modified example of the first embodiment.

FIG. 21 is a cross-sectional view of a semiconductor device according to a second embodiment.

FIG. 22 is a partial cross-sectional view of a circuit board according to the second embodiment.

FIG. 23A to FIG. 23C are diagrams illustrating a method of manufacturing the circuit board according to the second embodiment.

FIG. 24A to FIG. 24D are diagrams illustrating a method of manufacturing the semiconductor device according to the second embodiment.

FIG. 25 is a partial cross-sectional view of a circuit board according to a modified example of the second embodiment.

FIG. 26 is a partial cross-sectional view of a circuit board according to a third embodiment.

FIG. 27 is a partial cross-sectional view of a circuit board according to a modified example of the third embodiment.

FIG. 28 is a partial cross-sectional view of a circuit board according to a fourth embodiment.

### DESCRIPTION OF EMBODIMENT

### First Embodiment

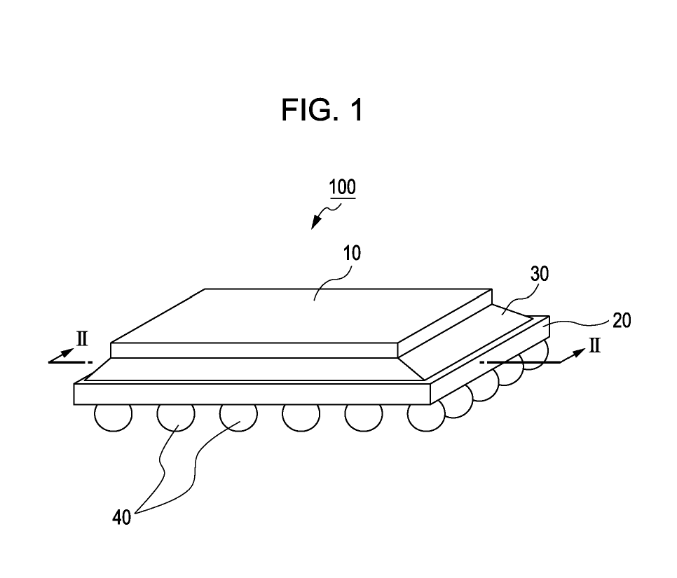

Hereinafter, a first embodiment will be described with reference to FIG. 1 to FIG. 20.

[Structure of Semiconductor Device]

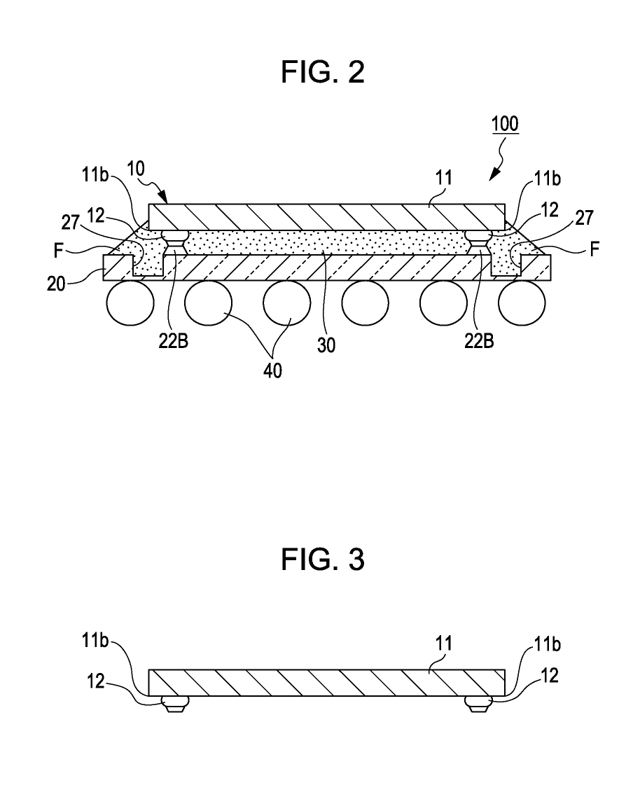

FIG. 1 is a perspective view of a semiconductor device 100 according to the first embodiment, and FIG. 2 is a cross-sectional view of the semiconductor device 100 according to the first embodiment and shows a cross section taken along the line II-II in FIG. 1.

As shown in FIG. 1 and FIG. 2, the semiconductor device 100 is a so-called BGA (Ball Grid Array) type semiconductor package and includes a semiconductor chip 10, a circuit board 20 on which the semiconductor chip 10 is mounted, an underfill resin 30 filled in the gap between the semiconductor chip 10 and the circuit board 20, and solder balls 40 mounted as external connection terminals on the circuit board 20.

The semiconductor chip 10 is assumed to be one obtained, for example, by producing a plurality of circuits in a semiconductor wafer and dividing the semiconductor wafer by dicing. However, the embodiment is not limited to the semiconductor chip, and another electronic component may be used.

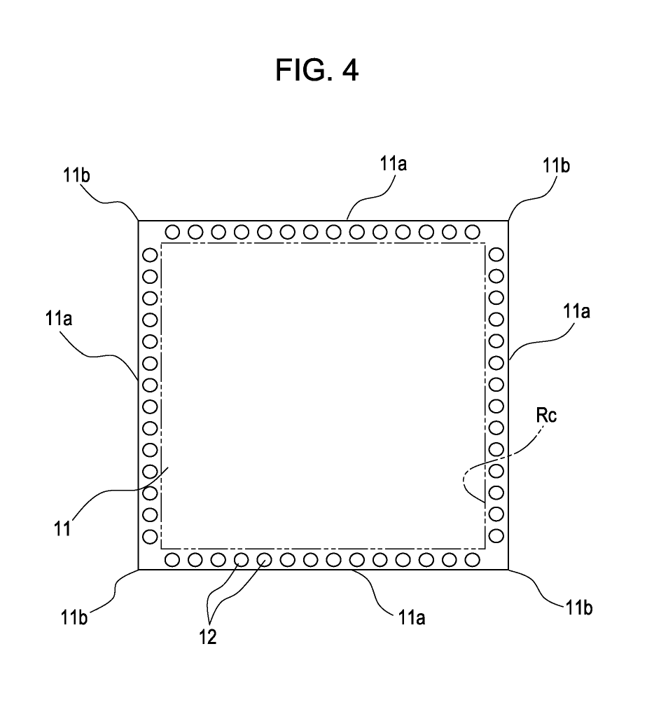

FIG. 3 is a side view of the semiconductor chip 10 according to the first embodiment, and FIG. 4 is a bottom view of the semiconductor chip 10 according to the first embodiment. As shown in FIG. 3 and FIG. 4, the semiconductor chip 10 includes a chip body 11 and a plurality of bumps 12 formed on a bottom surface of the chip body 11, namely, a surface of the chip body 11 that faces the circuit board 20.

The chip body 11 is formed in a substantially rectangular shape in a plan view. In other words, the chip body 11 has, at a portion facing the circuit board 20, the bottom surface of which the contour is defined by four sides 11a and four corners 11b. Each side 11a of the chip body 11 is set to have a length of about 4 mm. The thickness of the chip body 11 is set to about 0.2 mm. It should be noted that the embodiment is not limited thereto. For example, a planar shape of the chip body 11 may be a triangular shape, a pentagonal shape, or a shape of a polygon having more sides. Further, the planar shape of the chip body 11 may be a circular shape or an elliptical shape. The coefficient of linear expansion of the chip body 11 is about 2 ppm to 4 ppm and typically about 2.6 ppm.

The plurality of bumps 12 are arranged along the sides 11a of the chip body 11. The intervals of the bumps 12 are set to about 10 μm to 100 μm. As the material of the bumps 12, for example, gold may be used. As the method of producing the bumps 12, for example, ball bonding may be used.

The circuit board 20 is a so-called glass epoxy board. However, the embodiment is not limited thereto, and another printed board such as a glass composite board or a ceramic board may be used.

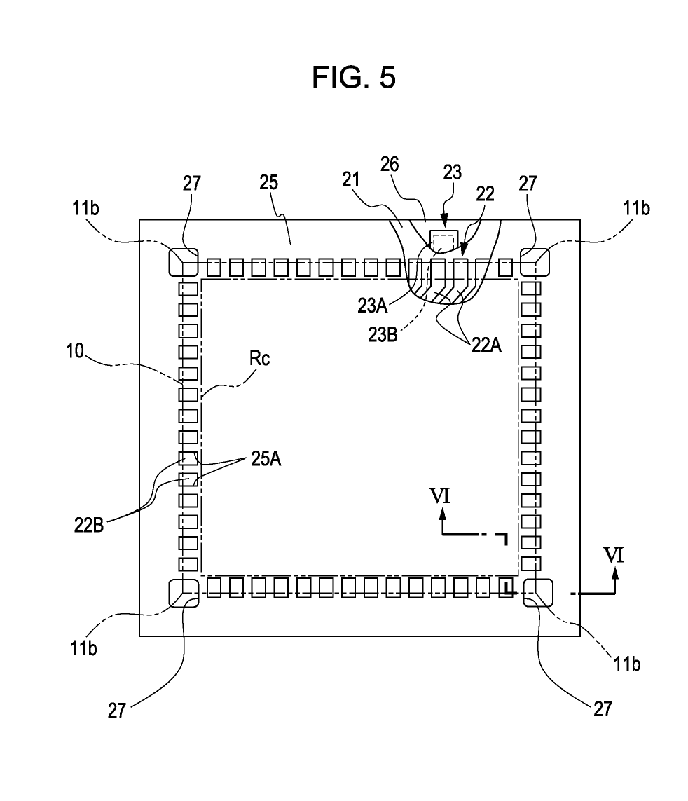

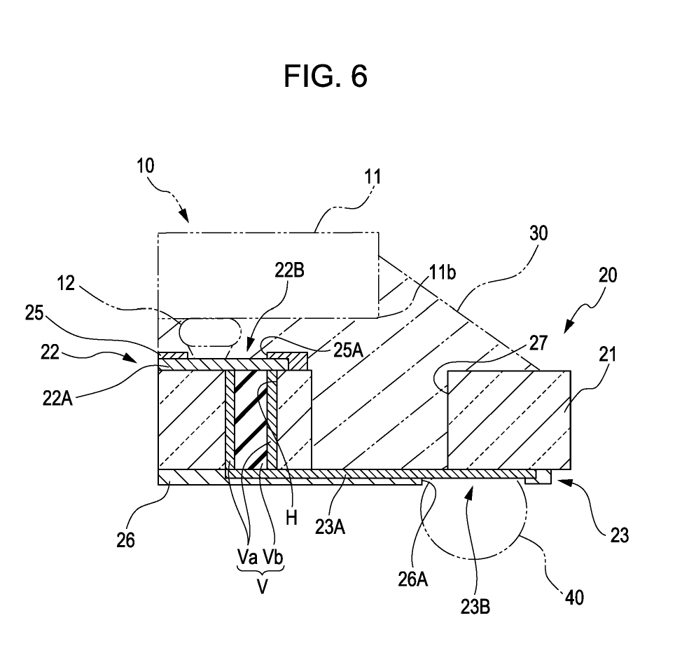

FIG. 5 is a plan view of the circuit board 20 according to the first embodiment, and FIG. 6 is a partial cross-sectional view of the circuit board 20 according to the first embodiment and shows a cross section taken along the line VI-VI in FIG. 5. As shown in FIG. 5 and FIG. 6, the circuit board 20 includes a core material 21, a first wiring layer 22, and a second wiring layer 23.

The core material 21 is obtained, for example, by impregnating an epoxy resin in a glass cloth. The core material 21 is formed in a substantially rectangular shape in a plan view and has a plurality of through holes H formed at predetermined positions. The thickness of the core material 21 is, for example, 150 μm to 250 μm. Each through hole H extends vertically through the core material 21, and a via V is embedded therein. The via V includes a conductive layer Va formed on the inner surface of the through hole H, and an insulating material Vb filled inside the conductive layer Va. The conductive layer Va electrically connects the first wiring layer 22 to the second wiring layer 23. As the material of the conductive layer Va, for example, Cu may be used. The proportion of the core material 21 in the circuit board 20 is high. Thus, the coefficient of thermal expansion of the entire circuit board 20 depends mainly on the core material 21, and is set to about 12 ppm to 16 ppm in the embodiment.

The first wiring layer 22 is formed on a top surface of the core material 21, namely, a surface of the core material 22 that faces the semiconductor chip 10, and includes a plurality of first wiring patterns 22A. The first wiring layer 22 is formed into a pattern shape of the first wiring patterns 22A by forming a metal film on the top surface of the core material 21 and then removing unnecessary portions from the metal film by etching. As the material of the first wiring layer 22, for example, Cu foil may be used. Further, a first solder resist 25 is formed on the top surface of the core material 21. As the material of the first solder resist 25, for example, an imide-based resin, specifically, a polyimide resin or the like may be used. The first solder resist 25 covers the first wiring patterns 22A but has openings 25A formed at positions corresponding to the bumps 12 of the semiconductor chip 10. Thus, the first wiring patterns 22A are partially exposed through the openings 25A of the first solder resist 25, and each exposed region forms a first electrode pad 22B. Thus, a plurality of the first electrode pads 22B are arranged on the top surface of the circuit board 20 and along each edge portion thereof in corresponding relation to the bumps 12 of the semiconductor chip 10.

The second wiring layer 23 is formed on a bottom surface of the core material 21, namely, a surface of the core material 21 on which the solder balls 40 are mounted, and includes a plurality of second wiring patterns 23A. The second wiring layer 23 is formed into a pattern shape of the second wiring patterns 23A by forming a metal film on the bottom surface of the core material 21 and then removing unnecessary portions from the metal film by etching. As the material of the second wiring layer 23, for example, Cu foil may be used. Further, a second solder resist 26 is formed on the bottom surface of the core material 21. As the material of the second solder resist 26, for example, an imide-based resin, specifically, a polyimide resin or the like may be used. The second solder resist 26 covers the second wiring patterns 23A but has a plurality of openings 26A formed in the entire bottom surface of the circuit board 20 in a matrix. Thus, the second wiring patterns 23A are exposed through the openings 26A of the second solder resist 26, and each exposed region forms a second electrode pad 23B. Thus, a plurality of the second electrode pads 23B is arranged on the bottom surface of the circuit board 20 in a matrix. The solder balls 40 are mounted to theses second electrode pads 23B, respectively. The solder balls 40 serve as external connection terminals when the semiconductor device 100 is mounted to another mounting board (mother board).

In the circuit board 20, recesses 27 are formed at positions, respectively, corresponding to the corners 11b of the semiconductor chip 10. The recesses 27 extend through the core material 21 of the circuit board 20 from its top surface to its bottom surface and reach the second wiring layer 23. Therefore, the interval between the semiconductor chip 10 and the circuit board 20 is larger at the positions corresponding to the corners 11b of the semiconductor chip 10 than at a center region Rc defined by the bumps 12 of the semiconductor chip 10, by the thickness of the core material 21. It should be noted that the recesses 27 do not necessarily need to extend through the core material 21, and, for example, the recesses 27 may be formed in the core material 21 so as to extend to an intermediate position therein. In the embodiment, the first electrode pads 22B are not formed at any of the positions corresponding to the corners 11b of the semiconductor chip 10, and thus the recesses 27 do not interfere with the first electrode pads 22B.

The underfill resin 30 is filled in the gap between the semiconductor chip 10 and the circuit board 20 to join the semiconductor chip 10 to the circuit board 20. In addition, by a contractive force generated when the material of the underfill resin 30 solidifies, the underfill resin 30 presses the bumps 12 of the semiconductor chip 10 against the first electrode pads 22B of the circuit board 20 to electrically connect the bumps 12 to the first electrode pads 22B. Therefore, a conductive adhesive or the like does not need to be additionally used for connecting the bumps 12 of the semiconductor chip 10 to the first electrode pads 22B of the circuit board 20. The peripheral portion of the underfill resin 30 protrudes around the semiconductor chip 10 to form a so-called fillet F. The fillet F extends from the top surface of the circuit board 20 to the sides of the semiconductor chip 10, and thus serves to enhance the joining strength between the semiconductor chip 10 and the circuit board 20 and to reduce stress generated at the peripheral portion of the underfill resin 30.

Further, the underfill resin 30 reduces stress applied to the connection portions of the bumps 12 and the first electrode pads 22B by being filled in the gap between the semiconductor chip 10 and the circuit board 20. For example, stress generated between the semiconductor chip 10 and the circuit board 20 with deformation of the semiconductor chip 10 or the circuit board 20 is applied to not only the connection portions of the bumps 12 and the first electrode pads 22B but also the underfill resin 30. Thus, concentration of stress on the connection portions of the bumps 12 and the first electrode pads 22B is suppressed.

Moreover, the underfill resin 30 has a lower rigidity, namely, a lower elastic modulus than those of the semiconductor chip 10 and the circuit board 20. Thus, when the semiconductor chip 10 or the circuit board 20 deforms, the underfill resin 30 deforms similarly according to this deformation to absorb the deformation of the semiconductor chip 10 or the circuit board 20. As the underfill resin 30, for example, an epoxy-based resin, specifically, a material obtained by adding a filler made of silica to an epoxy resin, may be used. The elastic modulus of the underfill resin 30 depends on the components of the epoxy resin, the added amount of the filler, and the like.

The underfill resin 30 as described above is embedded in the recesses 27 formed in the core material 21 of the circuit board 20. Thus, the underfill resin 30 is thicker at the positions directly below the corners 11b of the semiconductor chip 10 than at the center region Rc defined by the plurality of bumps 12. In other words, the underfill resin 30 between the semiconductor chip 10 and the circuit board 20 is present more in regions directly below the corners 11b of the semiconductor chip 10 than in the other region. Thus, when the semiconductor chip 10 or the circuit board 20 deforms, the more amount of the underfill resin 30 absorbs the deformation of the semiconductor chip 10 or the circuit board 20 at the positions directly below the corners 11b of the semiconductor chip 10. Therefore, an amount of deformation of the underfill resin 30 per unit volume is small at the positions directly below the corners 11b of the semiconductor chip 10. As a result, in the semiconductor device 100 according to the embodiment having the recesses 27, stress generated in the underfill resin 30 near the corners 11b of the semiconductor chip 10 is reduced as compared to that in a semiconductor device that does not have any recess 27.

For example, when the semiconductor chip 10 and the circuit board 20 are heated, the circuit board 20 deforms so as to increase separation from the semiconductor chip 10 with increasing the distance from the center of the semiconductor chip 10 toward the outside, owing to the difference in coefficient of thermal expansion between the semiconductor chip 10 and the circuit board 20. Thus, the distance between the semiconductor chip 10 and the underfill resin 30 is the maximum at a position most distant from the center of the semiconductor chip 10, namely, at the corners 11b of the semiconductor chip 10. However, since the semiconductor device 100 according to the embodiment has more underfill resin 30 at the positions directly below the corners 11b of the semiconductor chip 10 than at their vicinities, the amount of deformation of the underfill resin 30 per unit volume is small at these positions. Thus, when the semiconductor chip 10 and the circuit board 20 are heated, stress generated directly below the corners 11b of the semiconductor chip 10 is suppressed, and hence generation of a crack in the underfill resin 30 and separation at the interface between the underfill resin 30 and the semiconductor chip 10 or the circuit board 20 can be prevented. In other words, in the embodiment, by increasing the volume of the underfill resin 30, deformation of the circuit board 20 is absorbed without increasing stress in the underfill resin 30 located directly below the corners 11b of the semiconductor chip 10.

In particular, at the positions corresponding to the corners 11b of the semiconductor chip 10, separation of the semiconductor chip 10 and the underfill resin 30 is most likely to occur, since stress is concentrated on the underfill resin 30. Thus, a remarkable effect can be obtained by locating the recesses 27 in the circuit board 20 such that the recesses 27 extend directly below the corners 11b of the semiconductor chip 10.

Further, by embedding the underfill resin 30 in the recesses 27 of the circuit board 20, a so-called anchor effect occurs between the circuit board 20 and the underfill resin 30, and separation of the underfill resin 30 from the circuit board 20 is prevented.

[Simulation Results]

Hereinafter, simulation results of thermal stress generated in the underfill resin according to the first embodiment will be described. In the simulation, the heating temperature is set to 140° C., the coefficient of thermal expansion of the semiconductor chip 10 is set to 3.5 ppm, the coefficient of thermal expansion of the circuit board 20 is set to 11.0 ppm, the coefficient of thermal expansion of the underfill resin 30 is set to 37.0 ppm, the length of each side of the semiconductor chip 10 is set to 4.2 mm, the thickness of the semiconductor chip 10 is set to 0.2 mm, the length of each side of the circuit board 20 is set to 8.0 mm, the thickness of the circuit board is set to 0.22 mm, the thickness of the underfill resin 30 (the interval between the semiconductor chip 10 and the circuit board 20) is set to 40 μm, the length of the fillet F protruding around the semiconductor chip 10 is set to 0.2 mm, the length of each side of each recess is set to 0.4 mm, and the depth of each recess is set to 0.1 mm.

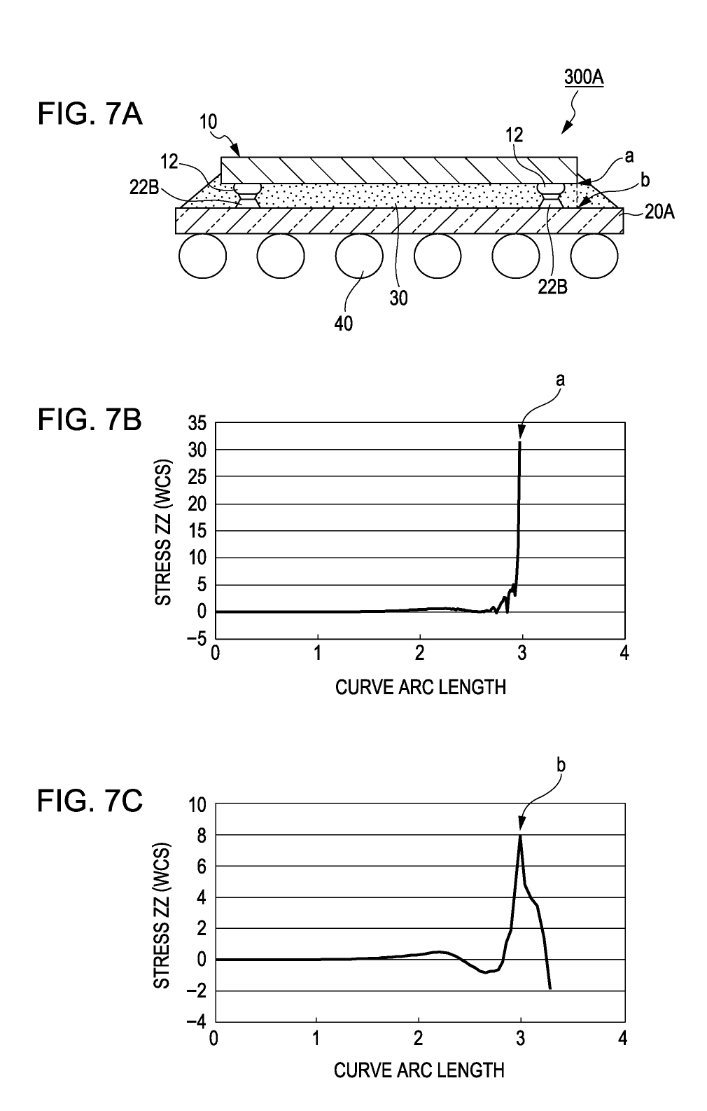

In each of stress distribution graphs in FIG. 7A to FIG. 10C, the horizontal axis indicates a distance from the center of the semiconductor chip, and the vertical axis indicates a value of stress generated in the underfill resin in a thickness direction. An index of the horizontal axis (curve arc length) is obtained by multiplying the distance (mm) from the center of the semiconductor chip by √2. Thus, the position at scale mark 3 on the horizontal axis corresponds to the position distant from the center of the semiconductor chip by about 2.1 mm, namely, the position of a corner of the semiconductor chip.

### Comparative Example 1

Comparative Example 1 is intended to explain thermal stress of the underfill resin 30 in a semiconductor device 300A that does not have any recess 27.

FIG. 7A is a schematic diagram of the semiconductor device 300A according to Comparative Example 1 that does not have any recess 27. FIG. 7B is a distribution diagram of thermal stress generated at the interface between the semiconductor chip 10 and the underfill resin 30 in the semiconductor device 300A. FIG. 7C is a distribution diagram of thermal stress generated at the interface between a circuit board 20A and the underfill resin 30 in the semiconductor device 300A.

As shown in FIG. 7B, in the semiconductor device 300A that does not have any recess 27, the thermal stress generated at the interface between the semiconductor chip 10 and the underfill resin 30 increases with increasing the distance from the center of the semiconductor chip 10 toward the outside, and is about 31.5 MPa (tensile stress) at the position directly below the corner of the semiconductor chip 10 (see an arrow a in FIG. 7B). In addition, as shown in FIG. 7C, the thermal stress generated at the interface between the circuit board 20A and the underfill resin 30 is about 8.1 MPa (tensile stress) at the position directly below the corner of the semiconductor chip 10 (see an arrow b in FIG. 7C).

### Comparative Example 2

Comparative Example 2 is intended to explain thermal stress of the underfill resin 30 in a semiconductor device 300B in which recesses 27B are located outward of the corners of the semiconductor chip 10.

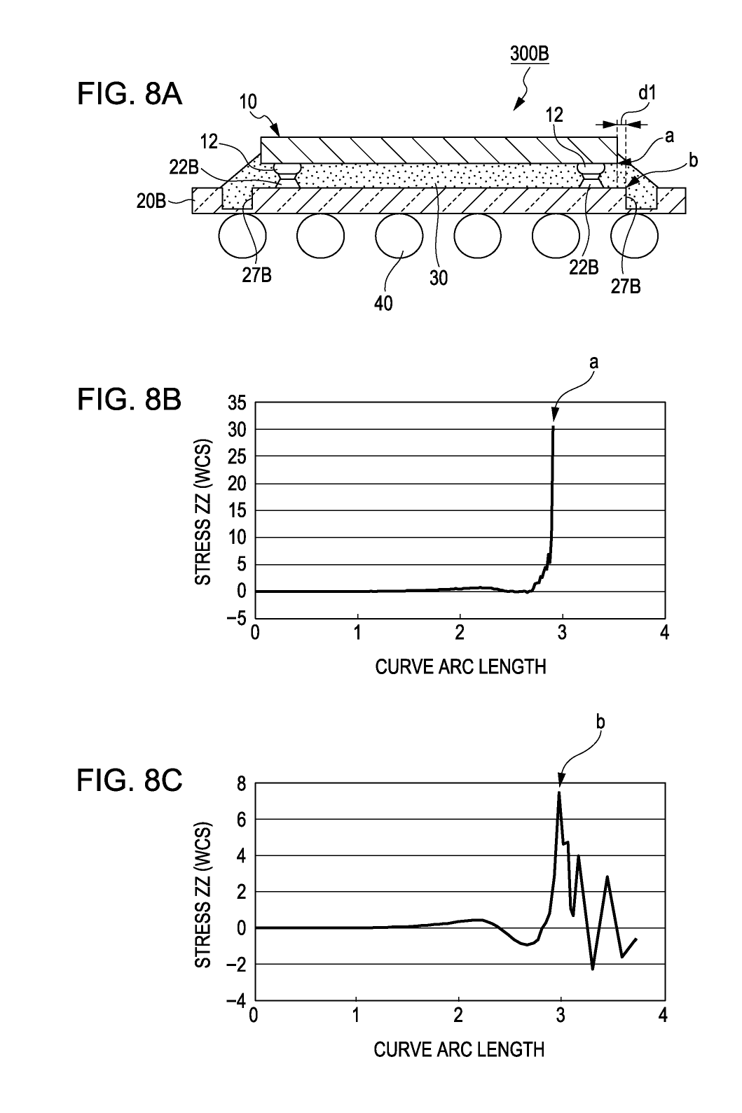

FIG. 8A is a schematic diagram of the semiconductor device 300B according to Comparative Example 2 in which the recesses 27B are located outward of the corners of the semiconductor chip 10, namely, at positions shifted outwardly from two mutually intersecting sides in the semiconductor chip 10 by d1 (=0.25 mm). FIG. 8B is a distribution diagram of thermal stress generated at the interface between the semiconductor chip 10 and the underfill resin 30 in the semiconductor device 300B. FIG. 8C is a distribution diagram of thermal stress generated at the interface between a circuit board 20B and the underfill resin 30 in the semiconductor device 300B.

As shown FIG. 8B, when the recesses 27B are located at the positions shifted outwardly from the semiconductor chip 10 by d1 (=0.25 mm), the thermal stress generated at the interface between the semiconductor chip 10 and the underfill resin 30 is about 28.6 MPa (tensile stress) at the position directly below the corner of the semiconductor chip 10 (see an arrow a in FIG. 8B). In addition, as shown in FIG. 8C, the thermal stress generated at the interface between the circuit board 20B and the underfill resin 30 is about 7.5 MPa (tensile stress) at the position directly below the corner of the semiconductor chip 10 (see an arrow b in FIG. 8C).

### Comparative Example 3

Comparative Example 3 is intended to explain thermal stress of the underfill resin 30 in a semiconductor device 300C in which recesses 27C are located inward of the corners of the semiconductor chip 10.

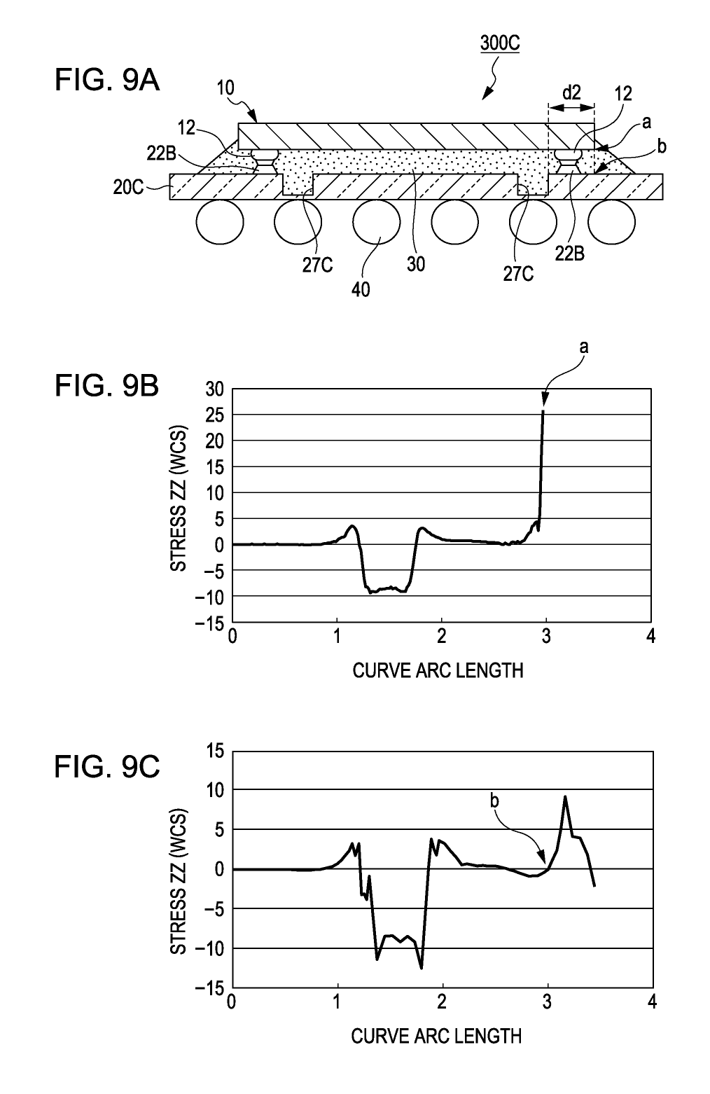

FIG. 9A is a schematic diagram of the semiconductor device 300C according to Comparative Example 3 in which the recesses 27C are located inward of the corners of the semiconductor chip 10, namely, at positions shifted inwardly from two mutually intersecting sides in the semiconductor chip 10 by d2 (=1.05 mm). FIG. 9B is a distribution diagram of thermal stress generated at the interface between the semiconductor chip 10 and the underfill resin 30 in the semiconductor device 300C. FIG. 9C is a distribution diagram of thermal stress generated at the interface between a circuit board 20C and the underfill resin 30.

As shown in FIG. 9B, when the recesses 27C are located at the positions shifted inwardly from the semiconductor chip 10 by d2 (=1.05 mm), the thermal stress generated at the interface between the semiconductor chip 10 and the underfill resin 30 is about 25.6 MPa (tensile stress) at the position directly below the corner of the semiconductor chip 10 (see an arrow a in FIG. 9B). In addition, as shown in FIG. 9C, the thermal stress generated at the interface between the circuit board 20C and the underfill resin 30 is about 0.0 MPa (tensile stress) at the position directly below the corner of the semiconductor chip 10 (see an arrow b in FIG. 9C).

### Example

Example is intended to explain thermal stress of the underfill resin 30 in the semiconductor device 100 in which the recesses 27 are located directly below the corners of the semiconductor chip 10.

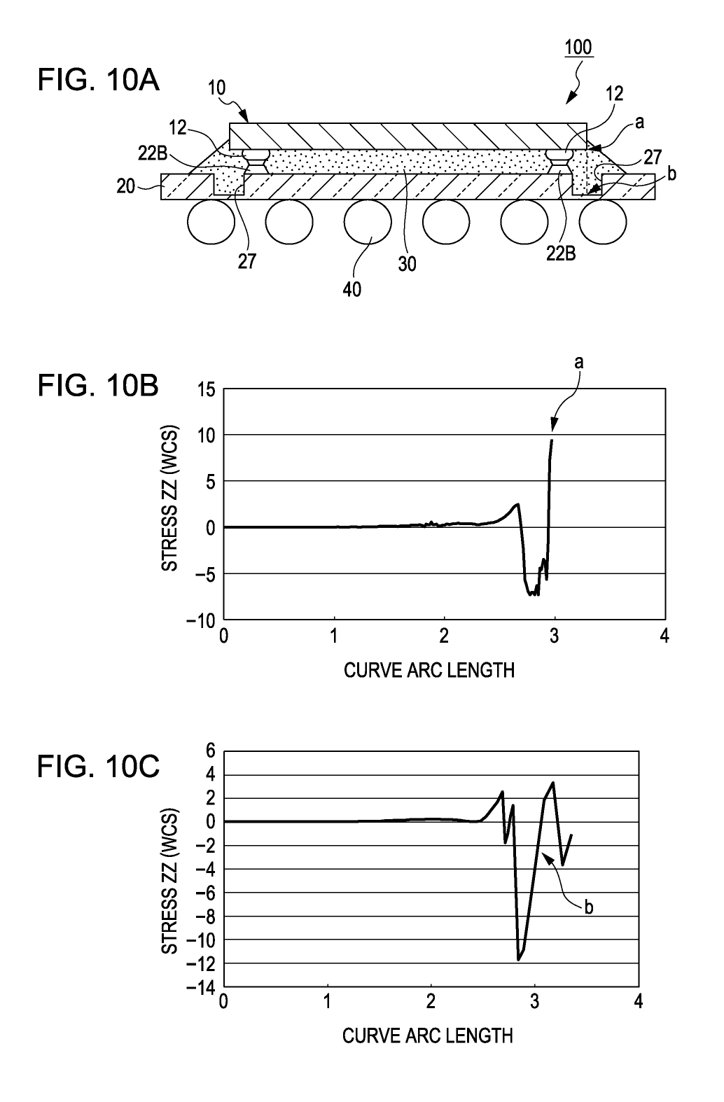

FIG. 10A is a schematic diagram of the semiconductor device 100 according to Example in which the recesses 27 are located directly below the corners of the semiconductor chip 10. FIG. 10B is a distribution diagram of thermal stress generated at the interface between the semiconductor chip 10 and the underfill resin 30 in the semiconductor device 100. FIG. 10C is a distribution diagram of thermal stress at the interface between the circuit board 20 and the underfill resin 30 in the semiconductor device 100.

As shown in FIG. 10B, in the semiconductor device 100 that has the recesses 27 directly below the corners of the semiconductor chip 10, the thermal stress generated at the interface between the semiconductor chip 10 and the underfill resin 30 is about 9.5 MPa (tensile stress) at the position directly below the corner of the semiconductor chip 10 (see an arrow a in FIG. 10B). In other words, it appears that the thermal stress generated at the interface between the semiconductor chip 10 and the underfill resin 30 is remarkably reduced as compared to those in Comparative Examples 1 to 3. In addition, the thermal stress generated at the interface between the circuit board 20 and the underfill resin 30 is about −3.1 MPa (compressive stress) at the position directly below the corner of the semiconductor chip 10 (see an arrow b in FIG. 10C). In other words, the thermal stress generated at the interface between the circuit board 20 and the underfill resin 30 is compressive stress that does not affect separation of the underfill resin 30.

As described above, from the simulation results as well, it appears that the thermal stress that causes separation of the underfill resin 30 can be reduced by forming the recesses 27 in the circuit board 20 so as to include the positions directly below the corners 11b of the semiconductor chip 10 and filling the underfill resin 30 therein.

[Manufacturing Method of Semiconductor Device]

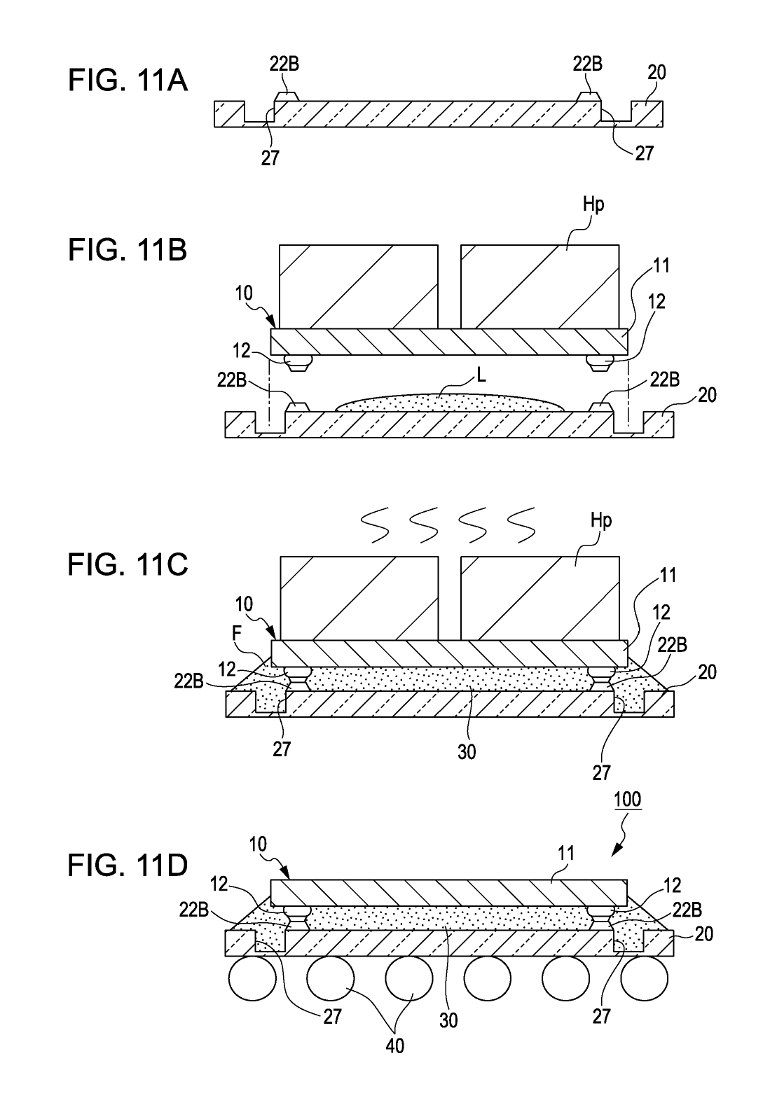

FIG. 11A to FIG. 11D are diagrams illustrating a method of manufacturing the semiconductor device 100 according to the first embodiment. It should be noted that in FIG. 11A to FIG. 11D, the detailed structure of the semiconductor device 100 is omitted and only the first electrode pads 22B are shown. Thus, please see FIG. 1 to FIG. 7C as necessary.

First, as shown in FIG. 11A, the circuit board 20 is prepared. Although not shown in FIG. 11A to FIG. 11D, the circuit board 20 includes the core material 21 such as a glass epoxy material, and the first wiring layer 22 and the second wiring layer 23 are formed on its top surface and bottom surface, respectively. The recesses 27 are respectively formed in the regions in the circuit board 20 corresponding to the four corners 11b of the semiconductor chip 10. The recesses 27 extend through the core material 21 and reach the second wiring layer 23. As the method of forming the recesses 27, for example, laser beam machining may be used. When laser beam machining is used, the recesses 27 can easily be formed if the second wiring layer 23 is used as a machining stop surface. Instead of laser beam machining, drilling may be used.

Next, as shown in FIG. 11B, an epoxy-based resin L is supplied to the top surface of the circuit board 20, for example, by a dispense method. The epoxy-based resin L used here is obtained, for example, by adding a filler such as silica to an epoxy resin. The supplied amount of the epoxy-based resin L is set to such a degree that when the semiconductor chip 10 is mounted, the gap between the semiconductor chip 10 and the circuit board 20 is filled and the fillet F is formed around the semiconductor chip 10. Then, the semiconductor chip 10 is attached to a bottom surface of a pressure head Hp, and the semiconductor chip 10 is positioned such that the bumps 12 of the semiconductor chip 10 face the first electrode pads 22B of the circuit board 20.

Next, as shown in FIG. 11C, the semiconductor chip 10 is lowered and pressed against the circuit board 20. Thus, the epoxy-based resin L is pressed and spread out by the semiconductor chip 10 to fill the recesses 27 of the circuit board 20 and to protrude around the semiconductor chip 10 to form the fillet F. The force applied at that time depends on the dimension of the semiconductor chip 10, the dimension of the bumps 12, or the number of the bumps 12, and is set, for example, to 2 kgf to 8 kgf. Then, the semiconductor chip 10 is heated by a heater (not shown) provided inside the pressure head Hp, to solidify the epoxy-based resin L in the gap between the semiconductor chip 10 and the circuit board 20. Thus, the epoxy-based resin L contracts, the semiconductor chip 10 is firmly joined to the circuit board 20, and the bumps 12 of the semiconductor chip 10 are electrically connected to the first electrode pads 22B of the circuit board 20.

Next, as shown in FIG. 11D, the solder balls 40 are mounted to the second electrode pads 23B of the circuit board 20, respectively. In this manner, the semiconductor device 100 according to the first embodiment is completed.

[Mounting Method to Another Mounting Board]

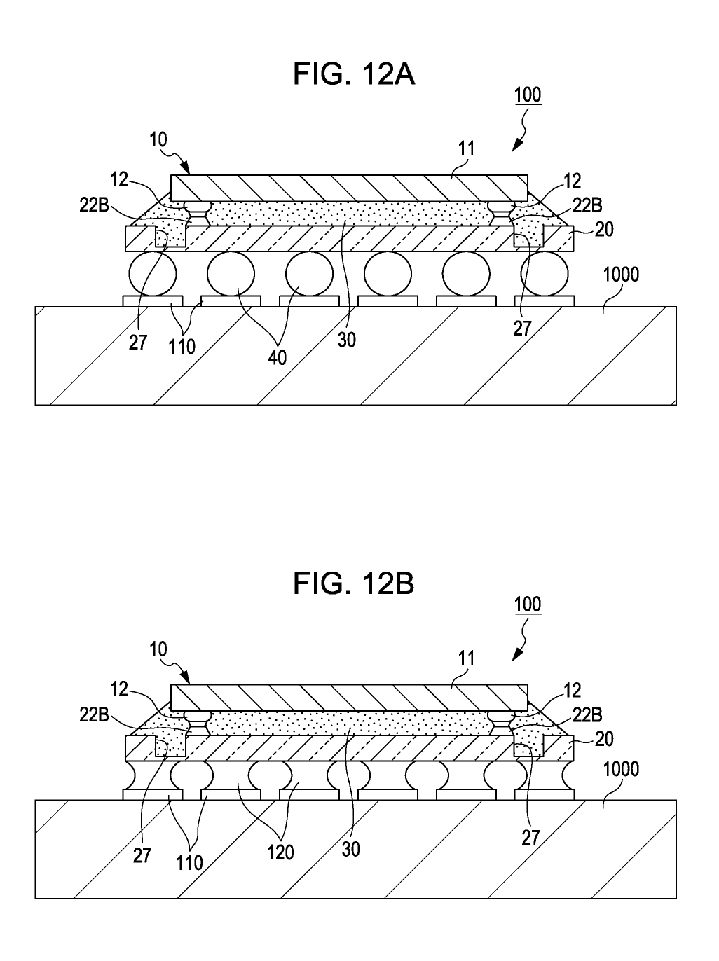

FIG. 12A and FIG. 12B are diagrams illustrating a method of mounting the semiconductor device 100 according to the first embodiment to another mounting board 1000. It should be noted that in FIG. 12A and FIG. 12B, the detailed structure of the semiconductor device 100 is omitted. Thus, please see FIG. 1 to FIG. 7C as necessary.

When mounting the semiconductor device 100 to the other mounting board 1000, the semiconductor device 100 is placed on the mounting board 1000 as shown in FIG. 12A. Then, the semiconductor device 100 and the mounting board 1000 are heated in a furnace to reflow the solder balls 40. Thus, the solder balls 40 melt and solidify to be solder members 120 as shown in FIG. 12B, and the second electrode pads 23B of the semiconductor device 100 are electrically connected to electrode pads 110 of the mounting board 1000. The reflow temperature depends on the material of the solder balls 40, and is set, for example, to 210° C. to 260° C. Therefore, the semiconductor chip 10 and the circuit board 20 thermally expand to generate thermal stress in the underfill resin 30. However, the semiconductor device 100 according to the embodiment includes the recesses 27, which are filled with the underfill resin 30, in the circuit board 20 and directly below the corners 11b of the semiconductor chip 10. Thus, the thermal stress of the underfill resin 30 directly below the corners 11b of the semiconductor chip 10 is reduced, and hence generation of a crack in the underfill resin 30 and separation at the interface between the underfill resin 30 and the semiconductor chip 10 or the circuit board are suppressed. The described mounting method to the other mounting board can be applied to the following embodiments and their modified examples.

[Modified Example of Circuit Board]

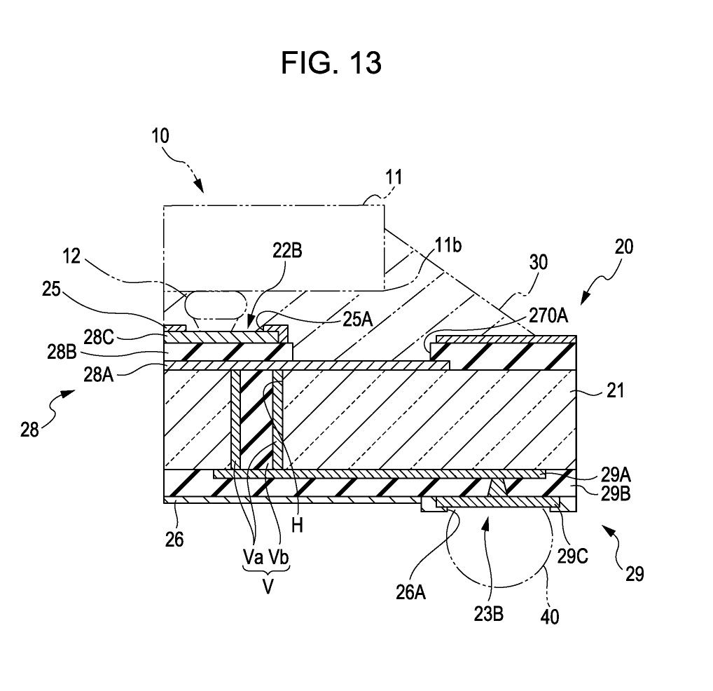

FIG. 13 is a partial cross-sectional view of a circuit board 20 according to the modified example of the first embodiment. In the first embodiment described above, the recesses 27 are formed in the core material 21 of the circuit board 20. However, when the circuit board 20 is a multilayer wiring board, for example, recesses 270A may be formed in an inter-layer insulating layer in the multilayer wiring board.

As shown in FIG. 13, the circuit board 20 according to the modified example is a multilayer wiring board and includes the core material 21, a first multilayered wiring 28 formed on the top surface of the core material 21, and a second multilayered wiring 29 formed on the bottom surface of the core material 21.

The first multilayered wiring 28 includes a first lower wiring layer 28A, a first inter-layer insulating layer 28B, and a first upper wiring layer 28C in order from the core material 21 side. The first lower wiring layer 28A and the first upper wiring layer 28C are electrically connected to each other by a via (not shown) embedded in the first inter-layer insulating layer 28B. As the material of the first inter-layer insulating layer 28B, for example, an epoxy resin or a polyimide resin may be used. Although not shown here, the first lower wiring layer 28A and the first upper wiring layer 28C include a plurality of first lower wiring patterns (not shown) and a plurality of first upper wiring patterns (not shown), respectively.

The second multilayered wiring 29 includes a second lower wiring layer 29A, a second inter-layer insulating layer 29B, and a second upper wiring layer 29C in order from the core material 21 side. The second lower wiring layer 29A and the second upper wiring layer 29C are electrically connected to each other by a via (not shown) embedded in the second inter-layer insulating layer 29B. As the material of the second inter-layer insulating layer 29B, for example, an epoxy resin or a polyimide resin may be used. Although not shown here, the second lower wiring layer 29A and the second upper wiring layer 29C include a plurality of second lower wiring patterns (not shown) and a plurality of second upper wiring patterns (not shown), respectively.

The recesses 270A according to the modified example are formed not in the core material 21 but in the first inter-layer insulating layer 28B so as to include the positions directly below the corners 11b of the semiconductor chip 10, that is, so as to extend across the positions directly below the corners 11b. The recesses 270A extend through the inter-layer insulating layer 28B and reach the first lower wiring layer 28A. The underfill resin 30 is filled in the gap between the semiconductor chip 10 and the circuit board 20 and also embedded in the recesses 270A formed in the first inter-layer insulating layer 28B.

When the multilayer wiring board is used as the circuit board 20 as described above, even though the recesses 270A are formed in the first inter-layer insulating layer 28B of the first multilayered wiring 28 and the underfill resin 30 is embedded therein, a more amount of the underfill resin 30 can be located directly below the corners 11b of the semiconductor chip 10.

[Modified Examples of Recesses]

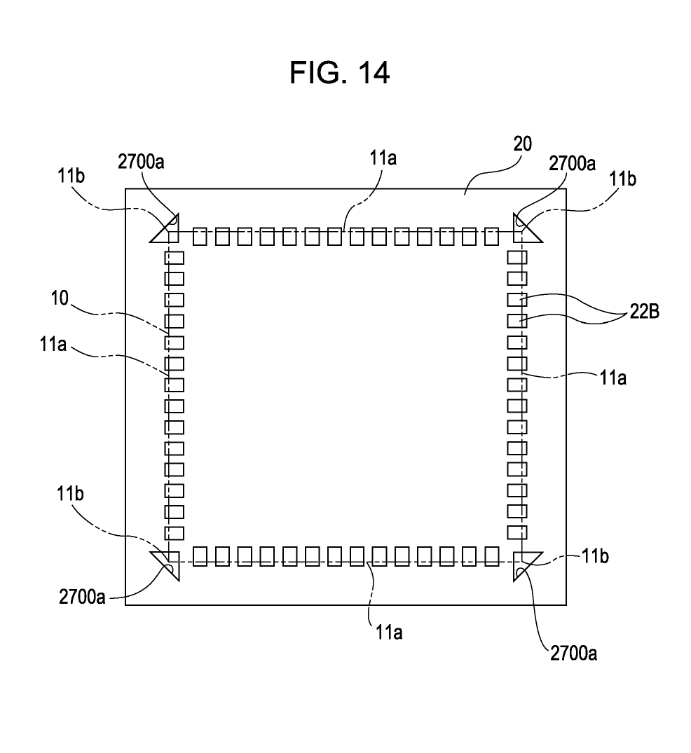

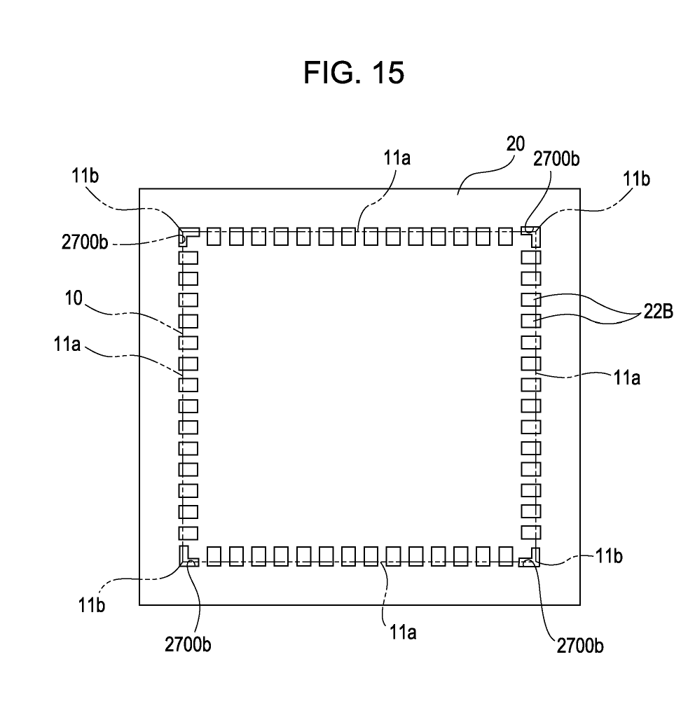

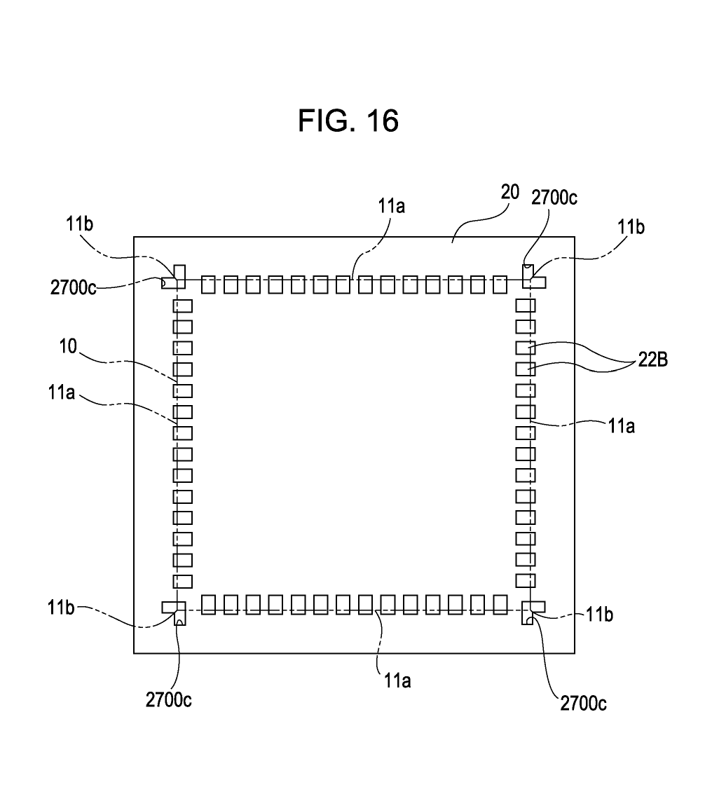

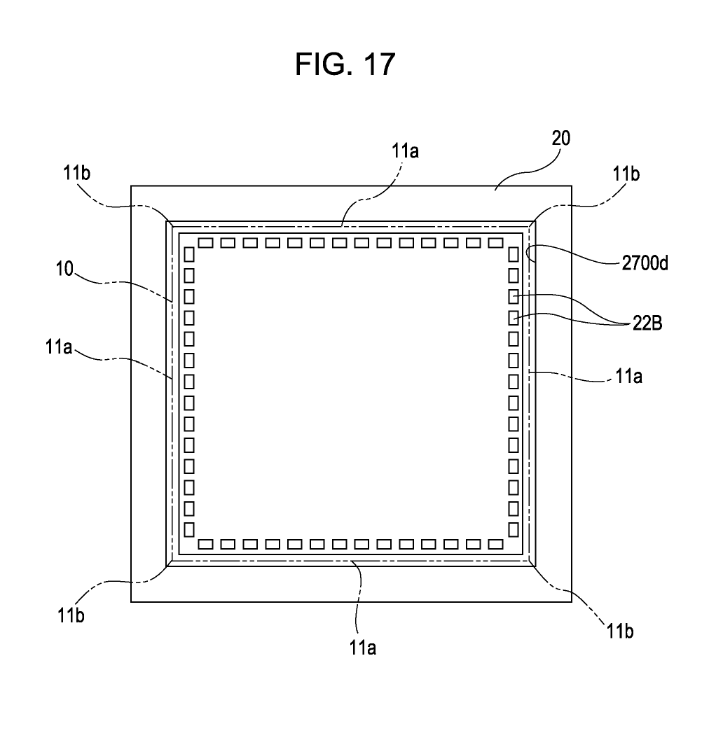

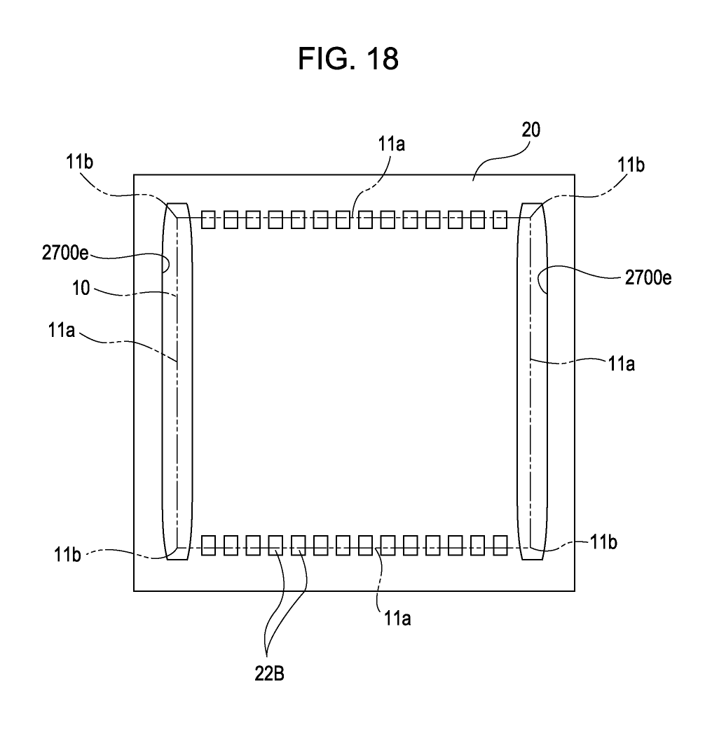

FIG. 14 to FIG. 18 are plan views of circuit boards 20 according to modified examples of the first embodiment. In the first embodiment described above, the recesses 27 formed in the circuit board 20 have substantially rectangular shapes in a plan view, but are not limited thereto. For example, as shown in FIG. 14, recesses 2700a having substantially triangular shapes in a plan view may be formed in the circuit board 20. As shown in FIG. 15 and FIG. 16, recesses 2700b and 2700c having substantially L shapes in a plan view may be formed in the circuit board 20. Further, as shown in FIG. 17, a recess 2700d having an annular shape (a rectangular frame shape) in a plan view may be formed in the circuit board 20 so as to surround the first electrode pads 22B. In this case, when the recess 2700d is located directly below the sides 11a of the semiconductor chip 10 so as to extend along the sides 11a, concentration of stress on the underfill resin 30 can be alleviated even near the sides 11a of the semiconductor chip 10. In addition, when the bumps 12 of the semiconductor chip 10 are arranged in two rows, that is, when the bumps 12 are arranged along the two sides 11a of the chip body 11 that face each other, long recesses 2700e may be formed in the circuit board 20 and directly below the remaining two sides 11a where no bumps 12 are arranged, so as to extend along these sides 11a, as shown in FIG. 18. The modified examples of the recesses 27 described here, that is, the recesses 2700a to 2700e, can be applied to the following embodiments and their modified examples.

[Modified Example of Semiconductor Device]

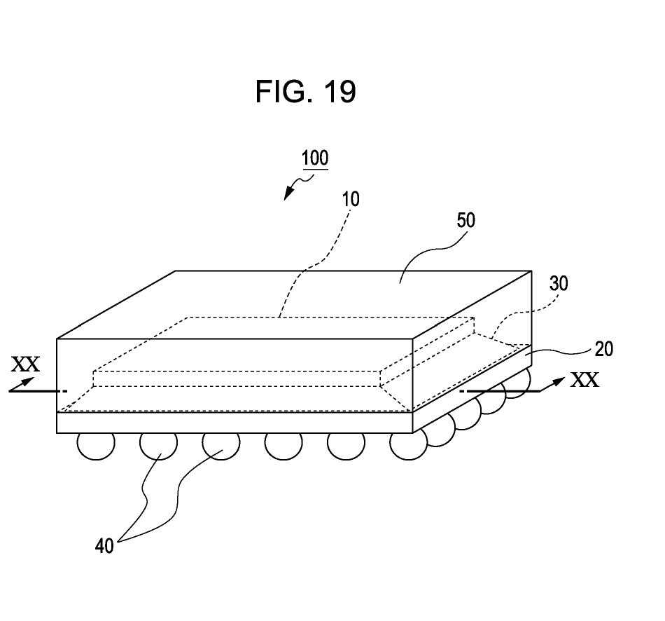

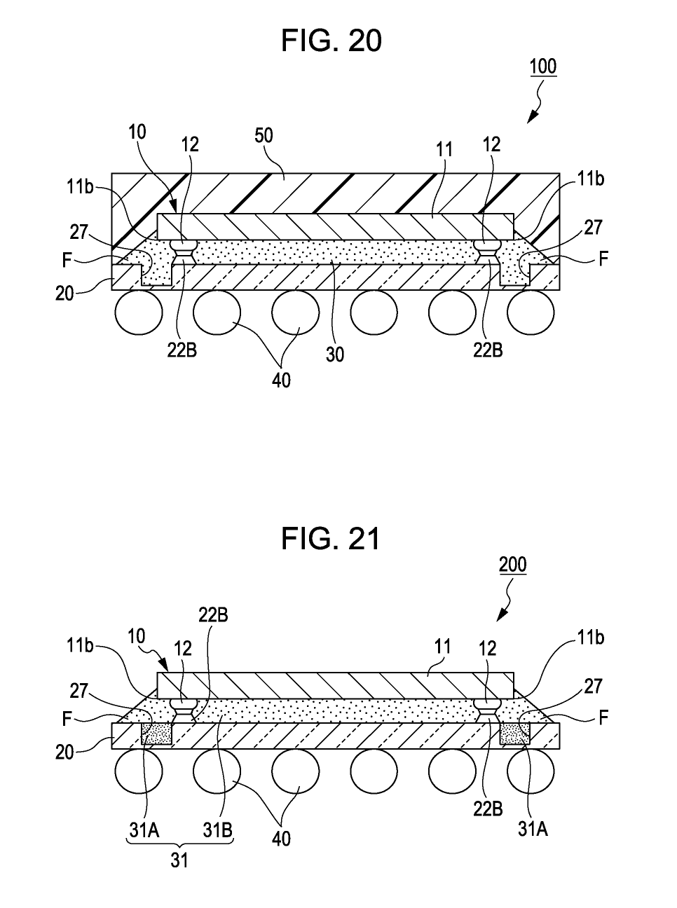

FIG. 19 is a perspective view of a semiconductor device 100 according to a modified example of the first embodiment, and FIG. 20 is a cross-sectional view of the semiconductor device 100 according to the modified example of the first embodiment and shows a cross section taken along the line XX-XX in FIG. 19.

According to need, as shown in FIG. 19 and FIG. 20, the semiconductor device according to the first embodiment may include a seal resin 50 for sealing the semiconductor chip 10 and the underfill resin 30. As the material of the seal resin 50, for example, a material obtained by a filler made of silica to an epoxy resin may be used. The added amount of the filler is higher than the added amount of the filler in the underfill resin 30. Thus, the seal resin 50 has a higher rigidity, that is, a higher elastic modulus than that of the underfill resin 30. When the semiconductor chip 10 and the underfill resin 30 are sealed by the seal resin 50, the seal resin 50 also thermally expands by heating (reflow) for mounting the semiconductor device 100 to the other mounting board 1000 (see FIG. 12A and FIG. 12B). Thus, the outer shape of the semiconductor device 100 may be, as a whole, a substantially M shape in a cross-sectional view. Specifically, in the semiconductor device 100, portions corresponding to the corners 11b of the semiconductor chip 10 are most distant from the mounting board 1000 (peaks of M), and regions inward and outward of the corners 11b of the semiconductor chip 10 are close to the mounting board. In this case as well, similarly to the first embodiment described above, thermal stress of the underfill resin 30 directly below the corners 11b of the semiconductor chip 10 is very great. However, in the semiconductor device according to the modified example, similarly to the first embodiment, the underfill resin 30 is present more in the regions directly below the corners 11b of the semiconductor chip 10 than in the other region. Thus, generation of a crack in the underfill resin 30 and separation at the interface between the underfill resin and the semiconductor chip 10 or the circuit board 20 are suppressed. The modified example of the semiconductor device 100 described here, that is, additionally providing the seal resin 50, can be applied to the following embodiments and their modified examples.

### Second Embodiment

Hereinafter, a second embodiment will be described with reference to FIG. 21 to FIG. 25.

[Structure of Semiconductor Device]

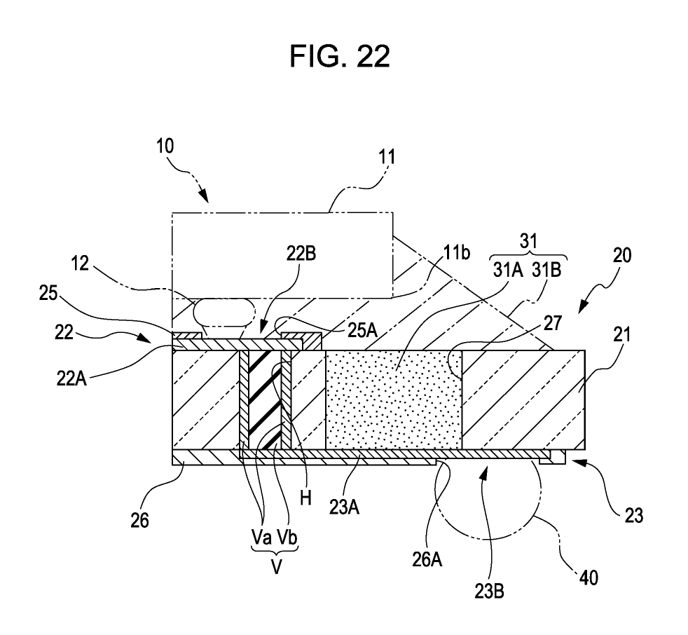

FIG. 21 is a cross-sectional view of a semiconductor device 200 according to the second embodiment, and FIG. 22 is a partial cross-sectional view of a circuit board 20 according to the second embodiment. As shown in FIG. 21 and FIG. 22, an underfill resin 31 according to the second embodiment includes first resin portions 31A and a second resin portion 31B. The first resin portions 31A are embedded in the recesses 27. A top surface of the first resin portion 31A is set at the same height as that of the top surface of the core material 21 of the circuit board 20. The second resin portion 31B is formed on the circuit board 20 and the first resin portion 31A and filled in the gap between the semiconductor chip 10 and the circuit board 20. The peripheral portion of the second resin portion 31B protrudes around the semiconductor chip 10 to form the so-called fillet F. Each of the first resin portion 31A and the second resin portion 31B has a lower rigidity, that is, a lower elastic modulus than those of the semiconductor chip 10 and the circuit board 20. Thus, when the semiconductor chip 10 or the circuit board 20 deforms, both the first resin portion 31A and the second resin portion 31B absorb the deformation of the semiconductor chip 10 or the circuit board 20.

As in the embodiment, when the underfill resin 31 is divided into the first resin portion 31A and the second resin portion 31B, the first resin portion 31A can be embedded in the recesses 27 of the circuit board 20 during manufacture of the circuit board 20. Thus, the underfill resin does not need to be embedded in the recesses 27 by using a so-called underfill resin first-in method or underfill resin last-in method. As a result, generation of a void in the first resin portion 31A embedded in the recesses 27, which is caused by entrained air, is suppressed. The underfill resin first-in method is a supply method in which a liquid underfill resin is applied to the top surface of a circuit board and pressed and spread out by a semiconductor chip. The underfill resin last-in method is a supply method in which after a semiconductor chip is mounted to a circuit board, a liquid underfill resin is injected into the gap between the semiconductor chip and the circuit board.

Further, in the embodiment, the rigidity, that is, the elastic modulus, of the first resin portion 31A may be set to be lower than that of the second resin portion 31B. By so doing, the amount of deformation of the semiconductor chip 10 or the circuit board 20 that is absorbed by the first resin portion 31A is large as compared to that when the materials of the first resin portion 31A and the second resin portion 31B are the same. Thus, the amount of deformation of the semiconductor chip 10 or the circuit board 20 that should be absorbed by the second resin portion 31B is reduced. Therefore, the rigidity, that is, the elastic modulus, of the second resin portion 31B filled in the gap between the semiconductor chip 10 and the circuit board 20 can be increased. As a result, the connection portions of the bumps 12 of the semiconductor chip 10 and the first electrode pads 22B of the circuit board 20 can be more firmly reinforced.

As each of the materials of the first resin portion 31A and the second resin portion 31B, for example, an epoxy-based resin, that is, a material obtained by a filler made of silica to an epoxy resin, may be used. When the elastic modulus of the first resin portion 31A is set to be lower than the elastic modulus of the second resin portion 31B, it is only necessary to adjust the added amount of the filler in the epoxy-based resin for each of the first and second resin portions 31A and 31B. In other words, it is only necessary to cause the added amount of the filler in the material of the first resin portion 31A to be lower than the added mount of the filler in the material of the second resin portion 31B.

[Manufacturing Method of Circuit Board]

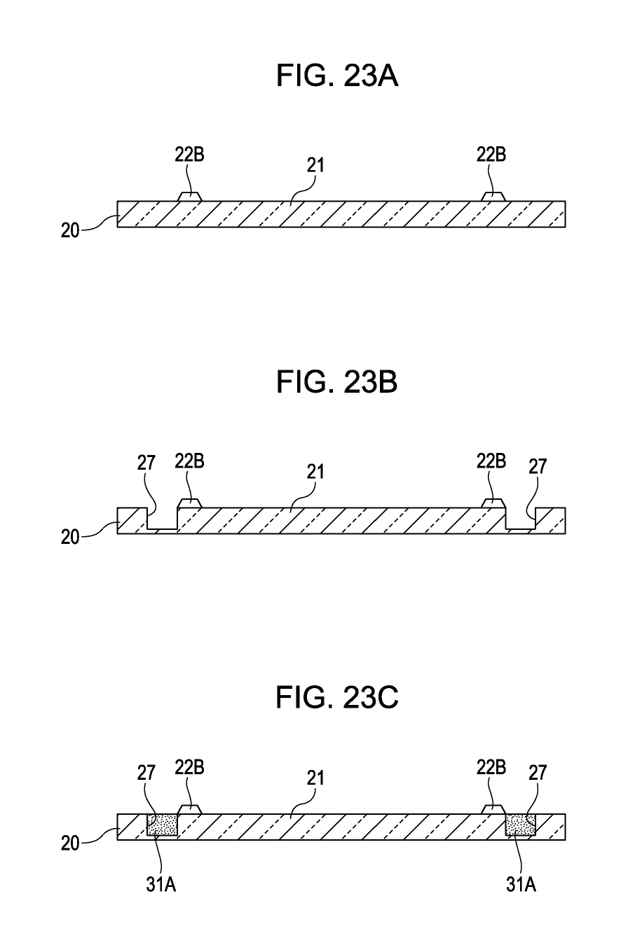

FIG. 23A to FIG. 23C are diagrams illustrating a method of manufacturing the circuit board 20 according to the second embodiment. It should be noted that in FIG. 23A to FIG. 23C, the detailed structure of the circuit board 20 is omitted, and only the first electrode pads 22B are shown. Thus, please see FIG. 21 and FIG. 22 as necessary.

First, as shown in FIG. 23A, the circuit board 20 is prepared. Although not shown in FIG. 23A to FIG. 23C, the circuit board 20 includes the core material 21 such as a glass epoxy material, and the first wiring layer 22 and the second wiring layer 23 are formed on the top surface and the bottom surface of the core material 21.

Next, as shown in FIG. 23B, the recesses 27 are formed in the core material 21 and directly below the four corners 11b of the semiconductor chip 10, respectively. The recesses 27 extend through the core material 21 and reach the second wiring layer 23. As the method of forming the recesses 27, for example, laser beam machining may be used. When laser beam machining is used, the recesses 27 can easily be formed if the second wiring layer 23 is used as a machining stop surface. Instead of laser beam machining, drilling may be used.

Next, as shown in FIG. 23C, an epoxy-based resin is supplied to the recesses 27, for example, by a dispense method, and heated together with the circuit board 20. Thus, the epoxy-based resin solidifies to form the first resin portions 31A in the recesses 27. The method of supplying the epoxy-based resin is not limited to the dispense method, and another method such as a printing method may be used. In this manner, the circuit board 20 used in the second embodiment is completed.

[Manufacturing Method of Semiconductor Device]

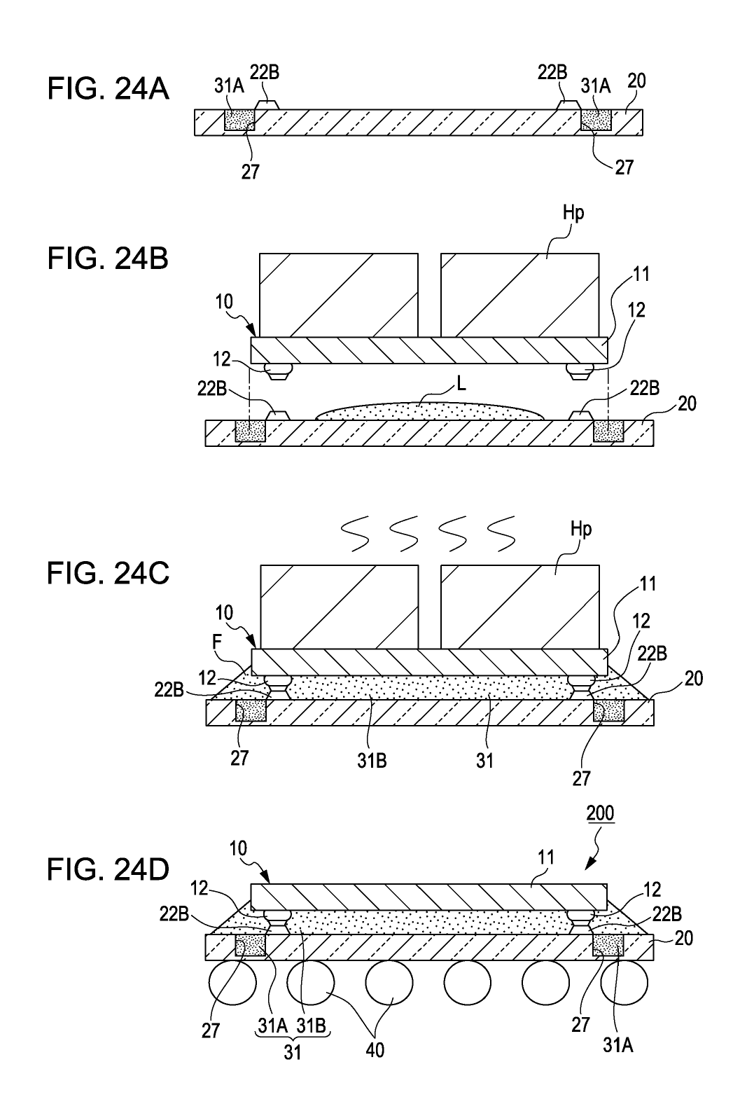

FIG. 24A to FIG. 24D are diagrams illustrating a method of manufacturing the semiconductor device 200 according to the second embodiment. It should be noted that in FIG. 24A to FIG. 24D, the detailed structure of the semiconductor device 200 is omitted, and only the first electrode pads 22B are shown. Thus, please see FIG. 21 and FIG. 22 as necessary.

First, as shown in FIG. 24A, the circuit board 20 is prepared. The circuit board 20 prepared here is the circuit board 20 manufactured by the manufacturing process shown in FIG. 23A to FIG. 23C.

Next, as shown in FIG. 24B, the epoxy-based resin L is supplied to the top surface of the circuit board 20, for example, by a dispense method. The epoxy-based resin L used here is the material of the second resin portion 31B, and is, for example, a material obtained by adding a filler such as silica to an epoxy resin. The supplied amount of the epoxy-based resin L is set to such a degree that when the semiconductor chip 10 is mounted, the gap between the semiconductor chip 10 and the circuit board 20 is filled and the fillet F is formed around the semiconductor chip 10. Then, the semiconductor chip 10 is attached to the bottom surface of the pressure head Hp, and the semiconductor chip 10 is positioned such that the bumps 12 of the semiconductor chip 10 face the first electrode pads 22B of the circuit board 20.

Next, as shown in FIG. 24C, the semiconductor chip 10 is lowered and pressed against the circuit board 20. Thus, the epoxy-based resin L is pressed and spread out by the semiconductor chip 10 to fill the gap between the semiconductor chip 10 and the circuit board 20 and to protrude around the semiconductor chip 10 to form the so-called fillet F. The force applied at that time depends on the dimension of the semiconductor chip 10, the dimension of the bumps 12, or the number of the bumps 12, and is set, for example to 2 kgf to 8 kgf. Then, the semiconductor chip 10 is heated by the heater (not shown) provided inside the pressure head Hp, to solidify the epoxy-based resin L in the gap between the semiconductor chip 10 and the circuit board 20. Thus, the epoxy-based resin L contracts, the semiconductor chip 10 is firmly joined to the circuit board 20, and the bumps 12 of the semiconductor chip 10 are electrically connected to the first electrode pads 22B of the circuit board 20.

Next, as shown in FIG. 24D, the solder balls 40 are mounted to the second electrode pads 23B of the circuit board 20, respectively. In this manner, the semiconductor device 200 according to the second embodiment is completed.

[Modified Example of Circuit Board]

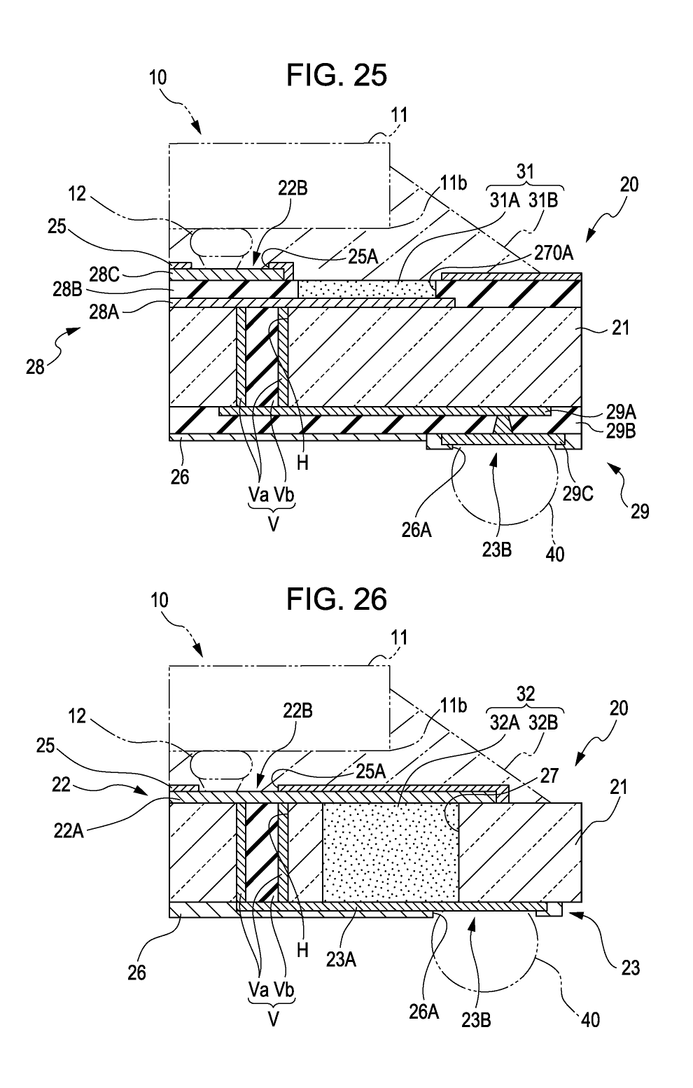

FIG. 25 is a partial cross-sectional view of a circuit board 20 according to a modified example of the second embodiment. In the second embodiment described above, the recesses 27 are formed in the core material 21 of the circuit board 20. However, when the circuit board 20 is a multilayer wiring board, for example, the recesses 270A may be formed in an inter-layer insulating layer in the multilayer wiring board.

As shown in FIG. 25, the circuit board 20 according to the modified example is a multilayer wiring board and includes the core material 21, the first multilayered wiring 28 formed on a top surface of the core material 21, and the second multilayered wiring 29 formed on a bottom surface of the core material 21.

The first multilayered wiring 28 includes the first lower wiring layer 28A, the first inter-layer insulating layer 28B, and the first upper wiring layer 28C in order from the core material 21 side. The first lower wiring layer 28A and the first upper wiring layer 28C are electrically connected to each other by a via (not shown) embedded in the first inter-layer insulating layer 28B. As the material of the first inter-layer insulating layer 28B, for example, an epoxy resin or a polyimide resin may be used. Although not shown here, the first lower wiring layer 28A and the first upper wiring layer 28C include a plurality of first lower wiring patterns (not shown) and a plurality of first upper wiring patterns (not shown), respectively.

The second multilayered wiring 29 includes the second lower wiring layer 29A, the second inter-layer insulating layer 29B, and the second upper wiring layer 29C in order from the core material 21 side. The second lower wiring layer 29A and the second upper wiring layer 29C are electrically connected to each other by a via (not shown) embedded in the second inter-layer insulating layer 29B. As the material of the second inter-layer insulating layer 29B, for example, an epoxy resin or a polyimide resin may be used. Although not shown here, the second lower wiring layer 29A and the second upper wiring layer 29C include a plurality of second lower wiring patterns (not shown) and a plurality of second upper wiring patterns (not shown), respectively.

The recesses 270A according to the modified example are formed not in the core material 21 but in the first inter-layer insulating layer 28B so as to include the positions directly below the corners 11b of the semiconductor chip 10, that is, so as to extend across the positions directly below the corners 11b. The recesses 270A extend through the inter-layer insulating layer 28B and reach the first lower wiring layer 28A. The first resin portions 31A of the underfill resin 31 are embedded in the recesses 270A formed in the first inter-layer insulating layer 28B. In addition, the second resin portion 31B of the underfill resin 31 is formed on the circuit board 20 and the first resin portion 31A and filled in the gap between the semiconductor chip 10 and the circuit board 20.

When the multilayer wiring board is used as the circuit board 20 as described above, even though the recesses 270A are formed in the first inter-layer insulating layer 28B of the first multilayered wiring 28 and the first resin portions 31A of the underfill resin 31 are embedded therein, a more amount of the underfill resin 31 can be located directly below the corners 11b of the semiconductor chip 10.

### Third Embodiment

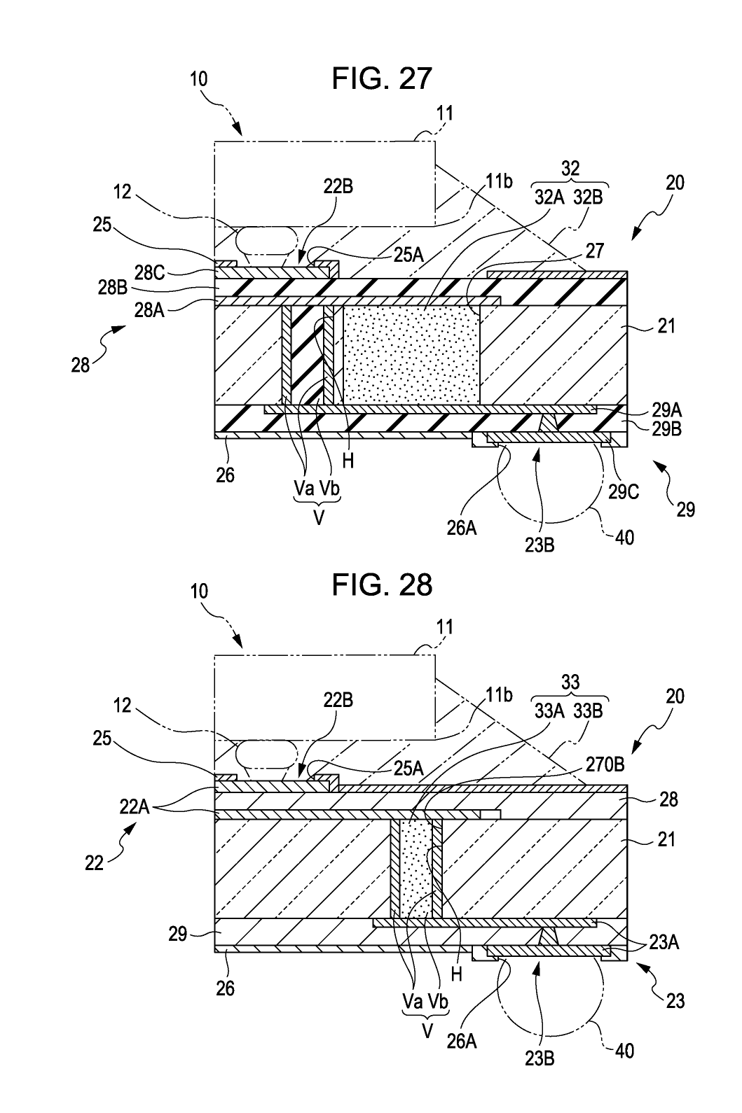

Hereinafter, a third embodiment will be described with reference to FIG. 26 and FIG. 27.

[Structure of Circuit Board]

FIG. 26 is a partial cross-sectional view of a circuit board 20 according to the third embodiment. As shown in FIG. 26, an underfill resin 32 according to the third embodiment includes first resin portions 32A and a second resin portion 32B. Further, recesses 27 according to the third embodiment are closed by the first wiring layer 22 of the circuit board 20. In other words, the first resin portion 32A and the second resin portion 32B are separated from each other by the first wiring layer 22. Thus, even when great stress (tensile stress) is generated owing to solidification and contraction of the underfill resin 32, since movements of the first resin portions 32A and the second resin portion 32B are blocked by the first wiring layer 22, separation at the interfaces between the first resin portions 32A and the inner surfaces of the recesses 27 and separation at the interface between the second resin portion 32B and the semiconductor chip 10 are prevented.

[Modified Example of Circuit Board]

FIG. 27 is a partial cross-sectional view of a circuit board 20 according to a modified example of the third embodiment. As shown in FIG. 27, an underfill resin 32 according to the modified example includes the first resin portions 32A and the second resin portion 32B. Further, recesses 27 according to the modified example are closed by the first multilayered wiring 28 of the circuit board 20. In other words, the first resin portions 32A and the second resin portion 32B are separated from each other by the first multilayered wiring 28. Thus, even when great stress (tensile stress) is generated owing to solidification and contraction of the underfill resin 32, since large movements of the first resin portions 32A and the second resin portion 32B are blocked by the first multilayered wiring 28, separation at the interfaces between the first resin portions 32A and the recesses 27 and separation at the interface between the second resin portion 32B and the semiconductor chip 10 are prevented. As described above, when the circuit board 20 is a multilayer wiring board, the first resin portions 32A and the second resin portion 32B may be separated from each other by the first multilayered wiring 28 instead of the first wiring layer 22 according to the third embodiment described above.

### Fourth Embodiment

Hereinafter, a fourth embodiment will be described with reference to FIG. 28.

FIG. 28 is a partial cross-sectional view of a circuit board 20 according to the fourth embodiment. As shown in FIG. 28, in the fourth embodiment, the through holes H formed in the core material 21 of the circuit board 20 are used as recesses 270B. An insulating material Vb of a via V embedded in each through hole H is used as a first resin portion 33A of an underfill resin 33. In other words, the underfill resin 33 according to the fourth embodiment includes the first resin portion 33A formed from the insulating material Vb of the via V and a second resin portion 33B filled in the gap between the semiconductor chip 10 and the circuit board 20. When the via V formed in the circuit board 20 is located directly below the corner 11b of the semiconductor chip 10 as described above, the insulating material Vb of the via V absorbs deformation of the semiconductor chip 10 or the circuit board 20, and thus a recess does not need to additionally be formed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
an electronic component having a mounting surface with a contour including a plurality of sides and a plurality of corners;
a circuit board including a mounted surface that faces the mounting surface of the electronic component and having a recess formed at a position facing the corner of the electronic component;
a connection portion provided between the electronic component and the circuit board and electrically connecting the circuit board to the electronic component;
a first member embedded in the recess and having a rigidity lower than those of the electronic component and the circuit board; and
a second member provided between the electronic component and the circuit board and having a rigidity lower than those of the electronic component and the circuit board.

2. The electronic device according to claim 1, wherein the first member and the second member are integrally formed from a same material.

3. The electronic device according to claim 1, wherein the rigidity of the first member is lower than that of the second member.

4. The electronic device according to claim 1, further comprising a partition portion separating the first member and the second member from each other.

5. The electronic device according to claim 1, wherein the recess is located at a position facing the side of the electronic component so as to extend along the side.

6. The electronic device according to claim 1, wherein
the circuit board includes a core material, a first wiring layer formed on a first surface of the core material, the first surface being located on a side on which the electronic component is mounted, and a second wiring layer formed on a second surface of the core material, the second surface being opposite to the first surface, and
the recess extends through the core material from the first surface to the second surface and reaches the second wiring layer.

7. The electronic device according to claim 6, wherein the circuit board includes, on an inner surface of the recess, a conductive layer that electrically connects the first wiring layer to the second wiring layer.
